(19) United States
(12) Patent Application Publication
(10) Pub. No.: US 2011/0048528 A1
(43) Pub. Date: Mar. 3, 2011

(54) STRUCTURE OF A SOLAR CELL

(75) Inventors: Jian-Jang HUANG, Taipei City (TW); Cheng-Pin Chen, Luzhou City (TW); Pei-Hsuan Lin, Taipei City (TW)

(73) Assignee: National Taiwan University, Taipei City (TW)

(21) Appl. No.: 12/788,252

(22) Filed: May 26, 2010

(30) Foreign Application Priority Data
Aug. 31, 2009 (TW) 98129308

(51) Int. Cl. H01L 31/00

(52) U.S. Cl. 136/256

(57) ABSTRACT

A structure of a solar cell is provided. The structure of the solar cell includes a substrate, a base and a plurality of nanostructures. The base is disposed on the substrate. The nanostructures are disposed on a surface of the base, or a surface of the base includes the nanostructures, so as to increase light absorption of the structure.

This application claims the benefit of Taiwan application Serial No. 98129308, filed Aug. 31, 2009, the subject matter of which is incorporated herein by reference.

### BACKGROUND OF THE INVENTION

1. Field of the Invention

The invention relates in general to a structure of solar cell, and more particularly to a structure of solar cell with high photoelectric conversion efficiency.

2. Description of the Related Art

Due to the energy crisis, the whole world is engaged in the pursuit of all sorts of alternative energies. Of the alternative energy sources with great development potential such as hydraulic power, wind power, solar power, terrestrial heat, sea water, temperature difference, waves, and tides, the solar power has become a mainstream of the new energies. According to estimation, the energy that the sun illuminated on the surface of the earth per year is one million times of the energy annually consumed by people on the earth. If 1% of the inexhaustible energy of solar light can be converted into electric power by solar cells, the generated energy will suffice to meet people's needs of energy.

When the solar light enters a conventional solar cell, a large amount of solar light will be reflected by the surface of the conventional solar cell. As the reflected solar light cannot be used for photoelectric conversion, the conversion efficiency of conventional solar cell decreases accordingly. In addition, among the generally known technologies, there is a method which increases the photoelectric conversion efficiency by etching the surface of the solar cell. However, the manufacturing process of such solar cell is costly and time consuming and not suitable for large-scale production for civil uses.

Besides, when the solar light moves along with the rotation of the earth, the solar light cannot be vertically illuminated on the solar cell (that is, the contained angle between the normal of the solar cell surface and the incident light is not equal to zero). Thus, conventional solar cell is configured on the solar power tracking system to position the relative location between the solar cell and the solar light to achieve vertical incidence of the solar light (that is, the contained angle between the normal line of the solar cell surface and the incident light is equal to zero). However, the cost increases significantly.

### SUMMARY OF THE INVENTION

The invention is directed to a structure of solar cell. Nanostructures are applied to coarsen a surface of the solar cell so as to increase the light absorption rate of the solar cell with respect to the incident light.

According to a first aspect of the invention, a structure of solar cell including a substrate, a base and a plurality of nanostructures is provided. The base is disposed on the substrate. The nanostructures are disposed on a surface of the base, so as to increase light absorption of the structure.

According to a second aspect of the invention, a structure of solar cell including a substrate, a first base, a second base and a plurality of nanostructures is provided. The first base is disposed on the substrate. The second base is disposed on a surface of the first base. The nanostructures are disposed on a surface of the second base, so as to increase light absorption of the structure.

According to a third aspect of the invention, a solar cell structure including a substrate and a base is provided. The base is disposed on the substrate, and a surface of the base has a plurality of nanostructures so as to increase light absorption of the structure.

According to a fourth aspect of the invention, a solar cell structure including a substrate, a first base and a second base is provided. The first base is disposed on the substrate. The second base is disposed on a surface of the first base, and a surface of the second base has a plurality of nanostructures so as to increase light absorption of the structure.

The above and other aspects of the invention will become apparent from the following detailed description of the preferred but non-limiting embodiments. The following description is made with reference to the accompanying drawings.

### BRIEF DESCRIPTION OF THE DRAWINGS

FIG. 1 shows a cross-sectional view of a solar cell according to a first embodiment of the invention.

FIG. 2 shows a cross-sectional view of an example of the structure of a solar cell of FIG. 1 having coplanar electrodes.

FIG. 3 shows a cross-sectional view of an example of the structure of a solar cell of FIG. 1 having a top and a bottom electrode.

FIG. 4A shows a cross-sectional view of an example of the structure of a solar cell of FIG. 2.

FIG. 4B illustrates the bandgap distribution of a first semiconductor layer of FIG. 4A being a graded layer.

FIG. 4C shows a first semiconductor layer of FIG. 4A being a super lattice layer.

FIG. 5 shows a plurality of nanoparticles of FIG. 1 in a square arrangement.

FIG. 6 shows a plurality of nanoparticles of FIG. 1 in a hexagonal arrangement.

FIG. 7 illustrates a measurement system for measuring the optical response of the solar cell of FIG. 1.

FIG. 8 shows a curve chart of normalized photocurrents of the solar cell of FIG. 1 and a conventional solar cell, illuminated with a 500 nm incident light under different incident angles.

FIG. 9 shows a curve chart of the photocurrent difference of the solar cell of FIG. 1 and a conventional solar cell, illuminated with a 500 nm incident light under different incident angles.

FIG. 10 shows a cross-sectional view of a solar cell according to a second embodiment of the invention.

FIG. 11 shows a cross-sectional view of an example of the structure of a solar cell of FIG. 10.

### DETAILED DESCRIPTION OF THE INVENTION

An embodiment of the invention discloses a solar cell structure with nano-sized microstructures, that is, nanostructures (such as nanoparticles), disposed on a surface of a material used as solar cell absorber. The light absorption of the solar cell with respect to the incident light is enhanced through the structural relationship between the nanostructures and the absorber. Any solar cell structure can be adapted if the nanostructures can be disposed on the surface of the base of the solar cell to increase its light absorption efficiency. A number of embodiments are disclosed below for elaboration.

### First Embodiment

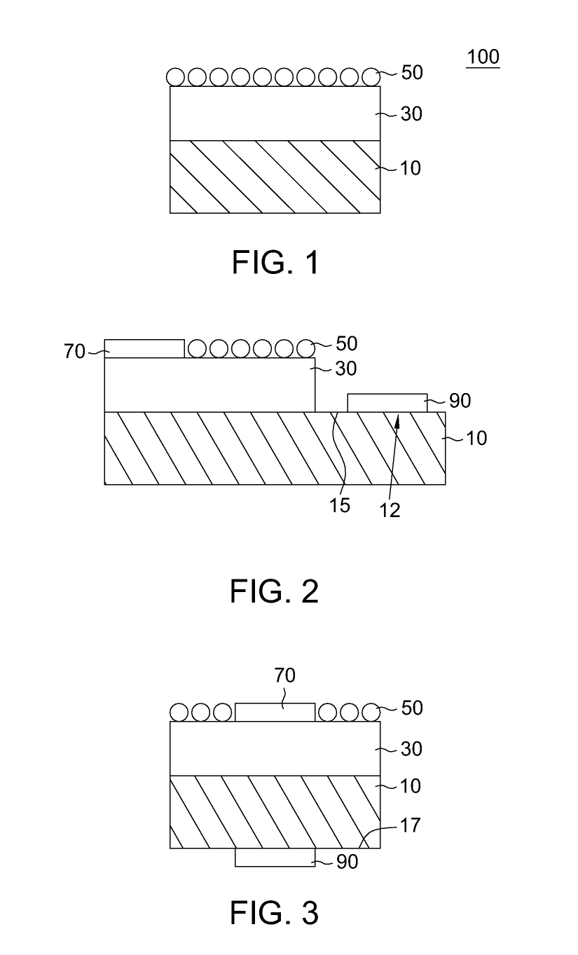

Referring to FIG. 1, a cross-sectional view of a solar cell according to a first embodiment of the invention is shown. The solar cell 100 includes a substrate 10, a base 30, and a plurality of nanostructures 50. The base 30 is disposed on the substrate 10. The nanostructures 50 such as nanoparticles are disposed on a surface of the base 30, or a surface of the base 30 has the nanostructures 50 to increase the light absorption of the entire solar cell 100.

In practical applications, electrodes can be disposed according to the structure of solar cell as shown in FIG. 1. FIG. 2 shows a cross-sectional view of an example of the structure of a solar cell of FIG. 1 having coplanar electrodes. In practical application, various implementations of disposition of electrodes on the solar cell 100 can be employed. According to an implementation shown in FIG. 2, a portion 12 of the substrate 10 extends over the base 30 for the disposition of the electrodes such as a first electrode 70 and a second electrode 90. For example, the first electrode 70 is disposed on a portion of the base 30, for example, a portion of a top surface of the base 30. The second electrode 90 is disposed on a portion 12 of a top surface 15 of the substrate 10.

Referring to FIG. 3, a cross-sectional view of an example of the structure of a solar cell of FIG. 1 having a top and a bottom electrode is shown. In this example, the second electrode 90 is directly disposed on a bottom surface 17 of the substrate 10, and the first electrode 70 is disposed on a portion of the base 30. In addition, as the implementation is not limited thereto, the solar cell structure according to the invention can be adapted in any solar cell if the nanostructures can be disposed on a surface of the base of the solar cell to increase the light absorption efficiency of the entire solar cell, and this holds true for the following embodiments.

The substrate 10 can be made from a low or high bandgap semiconductor material such as an N-type or P-type material, and the base 30 can be made from a high bandgap semiconductor material such as a P-type material. In another embodiment, the base 30 can be made from a high bandgap P-type material, and the substrate 10 can be made from a low bandgap semiconductor N-type material. In other examples, the substrate 10 and the base 30 can be made from a high bandgap semiconductor material and a low bandgap semiconductor respectively. Nevertheless, any solar cell can be employed for the implementation of the solar cell 100 if the junction of the substrate 10 and the base 30 forms a P—N junction according to the theory of the solar cell so as to achieve photoelectric conversion when the light is illuminated on the solar cell.

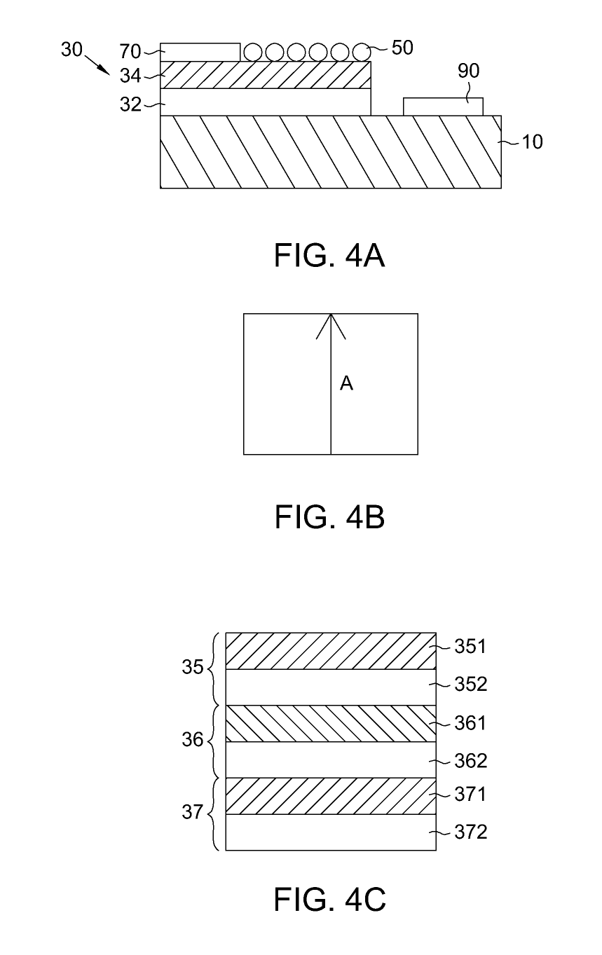

Referring to FIG. 4A, a cross-sectional view of an example of the structure of a solar cell of FIG. 2 is shown. For example, the base 30 includes a first semiconductor layer 32 and a second semiconductor layer 34. The first semiconductor layer 32, such as a graded layer, is disposed on the substrate 10. The second semiconductor layer 34 is disposed on the graded layer. The arrangement of the bandgaps of the materials of the substrate 10, the first semiconductor layer 32 (such as a graded layer) and the second semiconductor layer 34 will be exemplified by a number of implementations below.

Referring to FIG. 4B, a bandgap distribution of a first semiconductor layer of FIG. 4A being a graded layer is illustrated. In an embodiment, the substrate 10 can be made from a low bandgap semiconductor material, and the second semiconductor layer 34 can be made from a high bandgap semiconductor material. Meanwhile, the bandgap of the graded layer (that is, the first semiconductor layer) increases with distance away from the substrate 10, as indicated in the direction of arrow A. In another embodiment, the substrate 10 can be made from a high bandgap semiconductor material, and the second semiconductor layer 34 can be made from a low bandgap semiconductor material. In this case, the bandgap of the graded layer decreases with distance away from the substrate 10, as indicated in the direction of arrow A.

In FIG. 4A, the first semiconductor layer 32 can also be a super lattice layer, disposed on the substrate 10, and the second semiconductor layer 34 is disposed on the super lattice layer. The super lattice layer includes at least one thin film set, wherein one thin film set includes a first and a second thin film, the first thin film is disposed on the substrate 10, and the second thin film is disposed on the first thin film. The arrangement of the bandgaps of the substrate 10, the first semiconductor layer 32 (such as a super lattice layer) and the second semiconductor layer 34 will be exemplified by various implementations below.

Referring to FIG. 4C, a super lattice layer is taken as the first semiconductor layer 32 of FIG. 4A. In an embodiment, the super lattice layer includes three thin film sets 35-37. The substrate 10 can be made from a low bandgap semiconductor material, and the second semiconductor layer 34 can be made from a high bandgap semiconductor material. In addition, for each thin film set, the first thin films 351-371 can be made from high bandgap semiconductor materials, and the second thin films 352-372 can be made from low bandgap semiconductor materials.

In another embodiment, the substrate 10 is made from a high bandgap semiconductor material, and the second semiconductor layer 34 is made from a low bandgap semiconductor material. In this case, for each thin film set, the first thin films 351-371 can be made from low bandgap semiconductor materials, the second thin films 352-372 can be made from high bandgap semiconductor materials. Indeed, the number of thin films of the super lattice layer can be designed and adjusted according to requirements and the environment of application, and it is not limited to the above exemplifications.

In the present embodiment, the oxide semiconductor material can be, for example, zinc oxide material (ZnO), and examples of low bandgap semiconductor material include silicon (Si), germanium (Ge) or gallium arsenide (GaAs) material, and at least one material selected from the group consisting of germanium (Ge), indium (In), aluminum (Al), gallium (As), phosphorous (P) or antimony (Sb) or other alternative materials.

Further, the first electrode 70 and the second electrode 90 form respective ohmic contacts on the base 30 and the substrate 10 respectively. Examples of the first electrode 70 include titanium (Ti) and gold (Au). Examples of the second electrode 90 include nickel (Ni) and gold (Au). Other materials, locations or ways of forming ohmic contacts on the base and the substrate can also be employed for the implementation of the first and the second electrode such as the back electrodes of FIG. 3 or other ways of implementation.

As indicated in FIG. 1, the shape of the nanostructures 50 can be a circular or a non-circular geometric shape. Examples of the nanostructures include oxides, organic materials, semconductors, and metallic materials. Examples of the oxides include silicon dioxide (SiO₂), aluminum oxide (Al₂O₃) and titanium dioxide (TiO₂). Examples of the metallic materials include gold (Au), silver (Ag), nickel (Ni) and titanium (Ti). Examples of the organic materials include any suitable polymers such as polystyrene. The size of the nanostructures 50 ranges from about 10 nm to about 100 μm.

In the present embodiment, the nanostructures 50 are exemplified by a spherical structure and the material of the nanostructure is exemplified by a silicon dioxide (SiO₂) material. Besides, other different structures such as elliptical, powder, polygonal or other geometric structures capable of increasing the light absorption can be regarded as embodiments of the nanostructures 50.

For example, the refractive index of the nanostructures 50 (such as is 1.55) is less than the refractive index (about 3.6) of the base 30. When the solar light transmitted through the air (the refractive index is approximately equal to 1) is illuminated on the solar cell, the difference between the refractive index of the air and that of the base of the solar cell 100 is proportional to the reflective index of the solar light. That is, the greater the refractive index difference, the greater the reflective index. In other words, when the solar light is illuminated on the solar cell 100, a large amount of the incident light will be reflected off so that less amount of solar light can be illuminated on the solar cell 100 (that is, the photoelectric conversion efficiency deteriorates).

According to the solar cell of the present embodiment, the refractive index of the nanostructures 50 can be between the refractive index of the base 30 and that of the air, and the difference between the refractive index of the nanostructures 50 and that of the air is less than the difference between the refractive index of the base 30 and that of the air. Thus, the photoelectric conversion efficiency of the solar cell can be enhanced by the decrease in the reflective index of the solar light photoelectric. In addition, the nanostructures 50 are not limited to be those whose refractive indices are less than that of the base; nanostructures with refractive index equal to or greater than that of the base can also be employed to implement the present embodiment.

The disposition of a plurality of nanostructures 50 on a surface of the base 30 is disclosed in an exemplification below. In an example, the nanostructures 50 are nanoparticles and mixed with a solution such as isopropyl alcohol (IPA). Then, the mixed solution is dripped on the base 30. In the present embodiment, the nanostructures 50 are coated on the base 30 by a spinner according to the spin-coating method. The nanostructures 50 and the isopropyl alcohol are mixed according to a concentration ratio such as a weight percentage of nanostructure of 1.45% and a weight percentage of the isopropyl alcohol of 98.55%. The nanostructures 50 are disposed on the base 30 according to the spin-coating method for example. Besides, the user can further adjust the rotation speed or the duration corresponding to rotation speed with a spinner. Alternatively, the nanostructures 50 are disposed on the surface of the base 30 in multiple stages at different rotation speeds. Furthermore, the spin-coating process can be performed in two stages, such as a first stage and a second stage. In the first stage and the second stage, the nanostructures 50 are disposed at a first rotation speed and a second rotation speed respectively.

For example, in the first stage, the first rotation speed is 1000 rpm (that is, revolution per minute) and the duration is about 10 seconds; in the second stage, the second rotation speed is 4000 rpm and the duration is about 30 seconds. In other examples, the rotation speed, the duration and the number of stages can be adjusted according to the requirement of the operator. In addition, the operator can coat the nanostructures at one or two different rotation speeds, not limited thereto. In other examples, the rotation speed can be adjusted and designed according to the mixing ratio of the nanostructures 50 and the isopropyl alcohol.

In addition to the spin-coating method for disposing the nanostructures 50 on a surface of the base 30, the present embodiment can also be implemented by employing other methods, such as the etching method for disposing the nanostructures 50 on the surface of the base 30. For example, a blocking layer (such as photoresist, oxides or other material layers capable of blocking erosive liquids or gases) can be formed on the surface of the base 30 by wet etching method or dry etching method for disposing nanostructures on the surface of the base 30. However, the nanostructures 50 are not limited to nanoparticles, and any structures enabling the nanostructures 50 to be disposed on the surface of the base 30 to increase the light absorption efficiency of the entire solar cell can be used for implementing the present embodiment.

Next, after the spin-coating process is performed to the nanostructures 50, the arrangement of the nanostructures 50 has many ways of implementation. In an example, the nanostructures 50 disposed on the base 30 are in the form of single-layer arrangement. In the present embodiment, the solar cell 100 is exemplified by a plurality of nanostructures with single-layer arrangement, but is not limited thereto. In other embodiments, the nanostructures 50 disposed on the base 30 can be in the form of multi-layer arrangement, regular arrangement or random arrangement.

Besides, the abovementioned multiple arrangement method can be adjusted by changing the mixing ratio of the nanostructures 50 and the isopropyl alcohol or by changing the rotation speed.

Besides, the arrangement of the nanostructures 50 corresponds to a two-dimensional grating vector in the vector space. The refracted light of the incident light (that is, the solar light) entering the solar cell 100 with a minimum refraction angle can be obtained by considering the wave vector of the incident light and the two-dimensional grating vector. Since the projection of the incident light on the solar cell 100 is in a one-dimensional path, the two-dimensional grating vector can be simplified to a one-dimensional path from a two-dimensional space. That is, when the incident light is illuminated on the nanostructures 50, Bragg diffraction effect is considered in the one-dimensional path following the equation:

2 sin θ=[(2m+1)/2DG]λ/neff; (Equation1)

wherein θ indicates the incident angle, m denotes the order of diffraction, DG denotes the effective grating period, λ denotes the wavelength of the incident light, and neff denotes the effective refractive index of the nanostructures. Thus, the destructive interference occurs on the reflected light caused by illuminating the incident light on the nanostructures at an angle, according to equation 1, and results in the reduction of the reflected light of the solar light entered the solar cell 100 at that angle. The reflective index of the incident light on the surface of the solar cell is reduced and the photoelectricphotocurrent is increased so as to improve photoelectric conversion efficiency of the solar cell 100. Examples of the arrangements of the nanostructures are elaborated below.

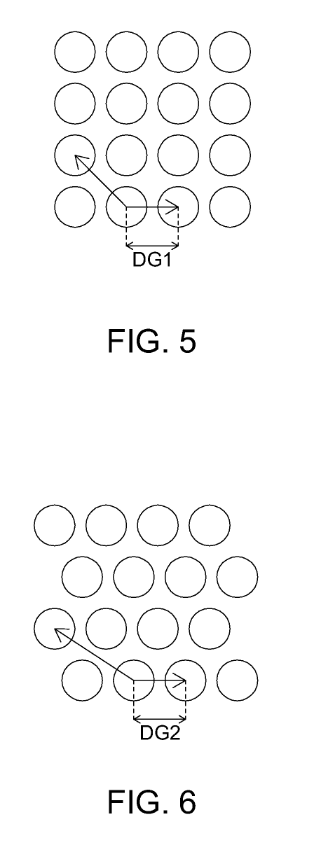

Referring to FIG. 5 and FIG. 6, FIG. 5 shows a square arrangement of a plurality of nanoparticles of FIG. 1f. FIG. 6 shows a hexagonal arrangement of nanoparticles of FIG. 1. In the basic mode (that is, m=1), the effective grating period DN will form a grating period DG1 and a grating period DG2 of the square and hexagonal arrangements respectively. When the wavelengths of the incident light are 500 nm, 550 nm and 600 nm, according to the theoretic calculation, the destructive interference occurs on the solar light entering the nanostructures 50 at the incident angle θ of 48°, 54°, and 62° respectively. In other words, less amount of the solar light will be reflected if the solar light enters the surface of the solar cell 100 at the angles of 48°, 54°, and 62°.

Thus, the incident angle corresponding to a wavelength at which destructive interference occurs can be adjusted by changing the arrangement of the nanostructures 50 or the size of the nanostructures 50. In other words, the diffraction effect (such as destructive interference) resulting from the periodic structure of the nanostructures relates to the gain of the photocurrent generated by the incident light of the wavelength on the solar cell. In an example, the grating period DN is 116 nm. In another example, the grating period can be adjusted by changing the size or the arrangement of the nanostructures 50.

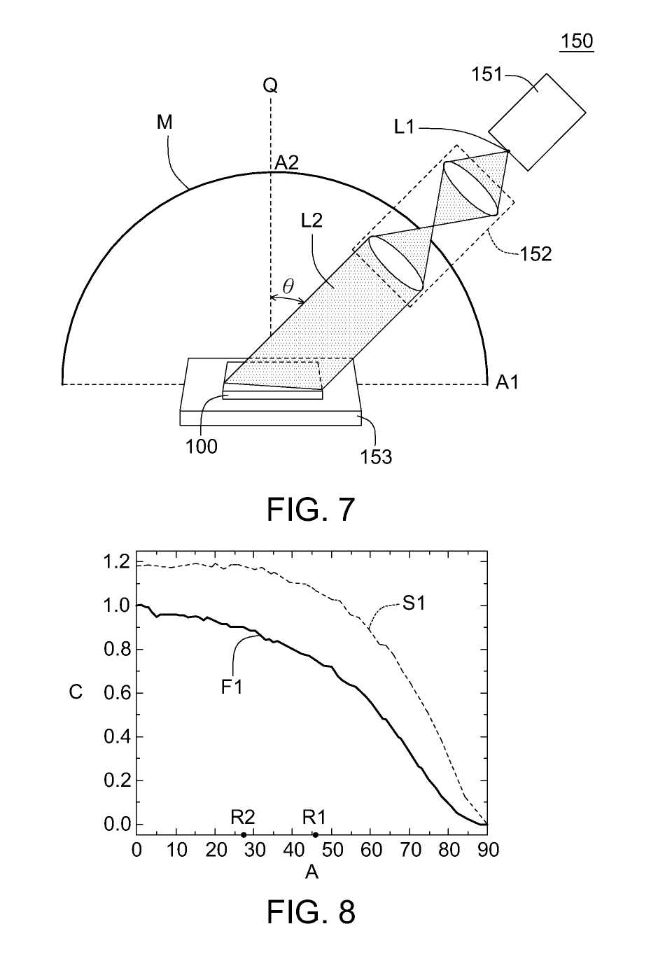

Referring to FIG. 7, a measurement system for measuring the optical response (i.e., quantum efficiency) for the solar cell of FIG. 1 is shown. As indicated in FIG. 2, the measurement system 150 includes a light source 151, a collimator 152 and a carrier 153. The light source 151 generates multiple incident lights with respective wavelengths, that is, to simulate the wavelengths that could be included in the solar light. The collimator 152 transforms the incident light L1 generated and radiated by the light source 151 (such as a point light source) into a parallel incident light L2, which is further illuminated on the solar cell 100 to simulate the solar light at a wavelength.

Furthermore, the measurement system 150 generates multiple incident lights with respective wavelengths by the light source 151 and illuminates the incident lights on the solar cell 100. The light source 151 moves from an angle A1 to an angle A2 (or from the angle A2 to the angle A1) along a path M to measure the photocurrent gain correspondingly generated by the solar cell 100 when the incident light L2 is illuminated on the solar cell 100 at different angles, wherein the wavelengths of the incident lights are 500 nm, 550 nm and 600 nm respectively for example. The angles A1 and A2 are 90° and 0° respectively for example. The incident angle θ is defined by the contained angle between the normal Q of the solar cell 100 and the incident light L2.

FIG. 8 shows a curve chart of normalized photocurrents of the solar cell of FIG. 1 and a conventional solar cell, illuminated with a 500 nm incident light. In FIG. 8, the horizontal axis denotes angle A and the verticle axis denotes the photocurrent C. As indicated in FIG. 8, when the wavelength of the incident light L2 on the solar cell 100 is 500 nm, a curve S1 shows an acceptance angle R1 for the 500 nm incident light L2 illuminated on the solar cell 100, and a curve F1 shows an acceptance angle R2 for the 500 nm incident light L2 illuminated on the conventional solar cell whose surface does not have nanostructures disposed thereon. The acceptance angle is defined as the incident angle of the incident light at or above 90% of the maximum photocurrent of the solar cell illuminated by the incident light. The maximum photocurrent is defined as the current generated by the incident light which is illuminated on the solar cell at 0° (that is, the angle between the normal and the incident light is 0°).

In an example, the acceptance angle R1 of the solar cell 100 is 46°, and the acceptance angle R2 of the conventional solar cell, without nanostructures disposed on its surface, is 27°. Compared with conventional solar cell, when the wavelength is 500 nm, the acceptance angle is increased by 19° for the solar cell 100 of the present embodiment. In other example, when the wavelengths are 550 nm and 600 nm, the acceptance angles are increased by 27° and 21° respectively. That is, the increase of acceptance angle of the light enables the photoelectric conversion of the solar light not vertically illuminated on the solar cell 100, wherein vertical illumination indicates the angle between the normal Q and the incident light L2 equal to 0°. In other words, the solar cell 100 enables the light absorption of the solar light at a wider range of incident angles, produces higher photocurrent gain, and thus enhances photoelectric conversion efficiency.

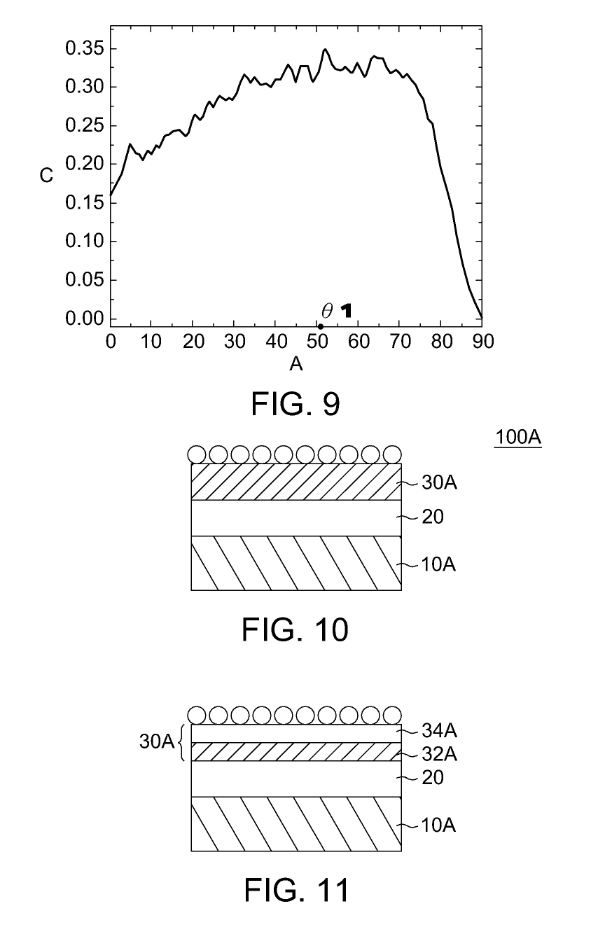

FIG. 9 shows a curve chart of the photocurrent difference of the solar cell of FIG. 1 and a conventional solar cell, illuminated with a 500 nm incident light under different incident angles. In FIG. 9, the horizontal axis denotes angle A and the verticle axis denotes photoelectricphotocurrent C. As indicated in FIG. 9, when the wavelength of the incident light L2 entering the solar cell 100 is 500 nm, the maximum difference between the photocurrents corresponding to the solar cell 100 and conventional solar cell occurs at an incident angle θ1, such as 52° for example. When the wavelengths of the incident light L2 are 550 nm and 600 nm, the maximum difference of the photocurrent occurs at incident angles θ2 and θ3, such as 62° and 63°, respectively, for example.

Thus, according to the theoretic calculation of the equation 1, when the wavelengths of the incident lights on the solar cell 100 are 500 nm, 550 nm, and 600 nm, the incident angles θ enabling the destructive interference of the reflected light of the incident light, that is, the reduced reflective index of the incident light, are 48°, 54° and 62° respectively. In other words, illuminating the incident light on the solar cell 100 at these incident angles decreases the amount of reflective light of the incident light. Thus, the incident angle at which destructive interference of the reflected light occurs can be adjusted according to relevant parameters of equation 1 for estimation. The incident angles can be determined, for example, by adjusting the size of the nanostructure to adjust the grating period and by changing the refractive index of the nanostructure.

### Second Embodiment

The solar cell 100A of the present embodiment differs from the solar cell 100 of the first embodiment in that the solar cell 100A includes a first base and a second base, which form a P—N junction, and that the substrate 10A is made from a transparent material, and the similarities are not repeated for the sake of brevity. To elaborate the solar cell of the present embodiment, a block diagram is disclosed below.

Referring to FIG. 10, a cross-sectional view of a solar cell according to a second embodiment is shown. The solar cell 100A has a substrate 10A, a first base 20, a second base 30A, and a plurality of nanostructures 50. The first base 20 is disposed on the substrate 10A. The second base 30A is disposed on the first base 20. The nanostructures 50 are disposed on a surface of the second base so as to increase the entire light absorption.

In the present embodiment, the substrate 10A can be made from a transparent material or a soft material. The transparent material is such as glass or quartz, and the soft material is such as plastics. The substrate 10A can also be made from a semiconductor material.

Referring to FIG. 11, a cross-sectional view of an example of the structure of a solar cell of FIG. 10 is shown. The second base 30A includes a first semiconductor layer 32A and a second semiconductor layer 34A. The first and the second semiconductor layer respectively correspond to the first semiconductor layer 32 and the second semiconductor layer 34 of the first embodiment, and their details are not repeated here for the sake of brevity. Besides, the bandgaps of the first semiconductor layer 32A and the second semiconductor layer 34A can be designed according to the bandgap of the first base 20.

In the present embodiment, the first base 20 can be made from a low bandgap semiconductor material such as a P-type material, and the second base 30A can be made from a high bandgap semiconductor material such as an N-type material. The low bandgap semiconductor material can be implemented according to an example of the first embodiment, and is not repeated here. In short, as is disclosed in the first embodiment, the solar cell can be implemented if the first base 20 and the second base 30A being bonded together can achieve photoelectric conversion according to the theory of the solar cell.

In practical application, the disposition of electrodes on the solar cell structure 100A of the present embodiment can be implemented in the manner of that of electrodes of the first embodiment disclosed in FIG. 2 or FIG. 3, and is not repeated here.

In other example, the solar cell 100A is implemented not subjected to the material of the substrate such as a glass substrate with higher hardness. For example, the substrate can be a substrate with lower hardness, such as a flexible plastics substrate, so as to increase the area of application of the solar cell.

Although the base of the first embodiment (or the second base of the second embodiment) is exemplified by a high bandgap semiconductor material such as an oxide semiconductor material, the base can also be implemented by using other semiconductor material with a high bandgap, compared to the substrate (or the first base of the second embodiment), or by using a semiconductor layer made from mixed materials or with multi-layer different materials. In short, any structures of solar cell can be used for implementing according to the invention if nanostructures can be disposed or included in the surface of a base of the solar cell to enhance its entire light absorption efficiency.

As disclosed above, the different embodiments of solar cell according to the invention lead to advantages exemplified as below:

(1) According to an embodiment disclosed above, the disposition of nanostructures reduces the reflective index of the incident light, and the manner of arrangement of the nanostructures improves the gain of the photocurrent generated by the incident light on the solar cell, thus increasing the acceptance angle and improving the photoelectric conversion efficiency of the solar cell. Accordingly, the solar cell can achieve improved efficiency and save cost without having to be disposed on a solar power tracking system.

(2) According to an embodiment disclosed above, the solar cell can be adapted in a substrate made from soft material or transparent material, so as to expand the area of application of the solar cell.

While the invention has been described by way of examples and in terms of preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A solar cell structure, comprising:
a substrate;
a base disposed on the substrate;
a plurality of nanostructures disposed on a surface of the base, so as to increase light absorption of the structure.

2. The solar cell structure according to claim 1, wherein the base comprises a graded layer and a semiconductor layer, the graded layer is disposed on the substrate, and the semiconductor layer is disposed on the graded layer.

3. The solar cell structure according to claim 2, wherein the substrate comprises a low bandgap semiconductor material, the semiconductor layer comprises a high bandgap semiconductor material, and bandgap of the graded layer increases with distance away from the substrate towards the semiconductor layer.

4. The solar cell structure according to claim 2, wherein the substrate comprises a high bandgap semiconductor material, the semiconductor layer comprises a low bandgap semiconductor material, and the graded layer has a graded bandgap which decreases with distance away from the substrate towards the semiconductor layer.

5. The solar cell structure according to claim 1, wherein the base comprises a super lattice layer and a semiconductor layer, the super lattice layer is disposed on the substrate, and the semiconductor layer is disposed on the super lattice layer.

6. The solar cell structure according to claim 5, wherein the super lattice layer comprises a thin film set comprising a first thin film and a second thin film, the first thin film is disposed on the substrate, and the second thin film is disposed on the first thin film.

7. The solar cell structure according to claim 6, wherein the substrate is made from a low bandgap semiconductor material, the semiconductor layer comprises a high bandgap semiconductor material, and the first and the second thin films respectively comprise a high bandgap semiconductor material and a low bandgap semiconductor material.

8. The solar cell structure according to claim 6, wherein the substrate comprises a high bandgap semiconductor material, the semiconductor layer comprises a low bandgap semiconductor material, and the first and the second thin films respectively comprise a low bandgap semiconductor material and a high bandgap semiconductor material.

9. The solar cell structure according to claim 1, wherein one of the substrate and the base comprises a low bandgap semiconductor material, the other of the substrate and the base comprises a high bandgap semiconductor material.

10. The solar cell structure according to claim 1, wherein the nanostructures have their sizes ranging from 10 nm to 100 μm.

11. The solar cell structure according to claim 1, wherein the nanostructures on the base are in the form of a single-layer arrangement or a multi-layer arrangement.

12. The solar cell structure according to claim 1, wherein the nanostructures comprise an oxide material, an organic material, a semiconductor or a metallic material.

13. The solar cell structure according to claim 1, further comprising:
a first electrode disposed on a portion of the base; and
a second electrode disposed on a portion of a top surface of the substrate or a bottom surface of the substrate.

14. A solar cell structure, comprising:
a substrate;
a first base disposed on the substrate;
a second base disposed on a surface of the first base;
a plurality of nanostructures disposed on a surface of the second base, so as to increase light absorption of the structure.

15. The solar cell structure according to claim 14, wherein the second base comprises a graded layer and a semiconductor layer, the graded layer is disposed on the first base, and the semiconductor layer is disposed on the graded layer.

16. The solar cell structure according to claim 14, wherein the second base comprises a super lattice layer and a semiconductor layer, the super lattice layer is disposed on the first base, and the semiconductor layer is disposed on the super lattice layer.

17. The solar cell structure according to claim 14, wherein one of the first base and the second base comprises a low bandgap semiconductor material, the other of the first base and the second base comprises a high bandgap semiconductor material, and the substrate comprises a transparent material.

18. The solar cell structure according to claim 14, wherein the nanostructures have their sizes ranging from 10 nm to 100 μm.

19. The solar cell structure according to claim 14, wherein the nanostructures on the base are in the form of a single-layer arrangement or a multi-layer arrangement.

20. The solar cell structure according to claim 14, wherein the nanostructures comprise an oxide material, an organic material, a semiconductor, or a metallic material.

21. The solar cell structure according to claim 14, further comprising:
a first electrode disposed on a portion of the second base; and
a second electrode disposed on a portion of the first base or the substrate.

22. A solar cell structure, comprising:
a substrate;
a base disposed on the substrate, wherein a surface of the base has a plurality of nanostructures disposed thereon so as to increase light absorption of the structure.

23. The solar cell structure according to claim 22, wherein the base comprises a graded layer and a semiconductor layer, the graded layer is disposed on the substrate, and the semiconductor layer is disposed on the graded layer.

24. The solar cell structure according to claim 23, wherein the substrate comprises a low bandgap semiconductor material, the semiconductor layer comprises a high bandgap semiconductor material, and the graded layer has a graded bandgap increasing with distance away from the substrate towards the semiconductor layer.

25. The solar cell structure according to claim 23, wherein the substrate comprises a high bandgap semiconductor material, the semiconductor layer comprises a low bandgap semiconductor material, and the graded layer has a graded bandgap decreasing with distance away from the substrate towards the semiconductor layer.

26. The solar cell structure according to claim 22, wherein the base comprises a super lattice layer and a semiconductor layer, the super lattice layer is disposed on the substrate, and the semiconductor layer is disposed on the super lattice layer.

27. The solar cell structure according to claim 26, wherein the super lattice layer comprises a thin film set comprising a first thin film and a second thin film, the first thin film is disposed on the substrate, and the second thin film is disposed on the first thin film.

28. The solar cell structure according to claim 27, wherein the substrate comprises a low bandgap semiconductor material, the semiconductor layer comprises a high bandgap semiconductor material, and the first and the second thin films respectively comprise a high bandgap semiconductor material and a low bandgap semiconductor material.

29. The solar cell structure according to claim 27, wherein the substrate comprises a high bandgap semiconductor material, the semiconductor layer comprises a low bandgap semiconductor material, and the first thin film and the second thin film respectively comprise a high bandgap semiconductor material and a low bandgap semiconductor material.

30. The solar cell structure according to claim 22, wherein one of the substrate and the base comprises a low bandgap semiconductor material, and the other of the substrate and the base comprises a high bandgap semiconductor material.

31. The solar cell structure according to claim 22, wherein the nanostructures have their sizes ranging from 10 nm to 100 μm.

32. The solar cell structure according to claim 22, wherein the nanostructures on the base are in the form of a single-layer arrangement or a multi-layer arrangement.

33. The solar cell structure according to claim 22, wherein the materials of the nanostructures comprise an oxide material, an organic material, a semiconductor, or a metallic material.

34. The solar cell structure according to claim 22, further comprising:
a first electrode disposed on a portion of the base; and
a second electrode disposed on a portion of a top or a bottom surface of the substrate.

35. A solar cell structure, comprising:
a substrate;
a first base disposed on the substrate;
a second base disposed on a surface of the first base, wherein a surface of the second base has a plurality of nanostructures disposed thereon so as to increase light absorption of the structure.

36. The solar cell structure according to claim 35, wherein the second base comprises a graded layer and a semiconductor layer, the graded layer is disposed on the first base, and the semiconductor layer is disposed on the graded layer.

37. The solar cell structure according to claim 35, wherein the second base comprises a super lattice layer and a semiconductor layer, the super lattice layer is disposed on the first base, and the semiconductor layer is disposed on the super lattice layer.

38. The solar cell structure according to claim 35, wherein one of the first base and the second base comprises a low bandgap semiconductor material, the other of the first base and the second base comprises a high bandgap semiconductor material, and the substrate comprises a transparent material.

39. The solar cell structure according to claim 35, wherein the nanostructures have their sizes ranging from 10 nm to 100 μm.

40. The solar cell structure according to claim 35, wherein the nanostructures on the base are in the form of a single-layer arrangement or a multi-layer arrangement.

41. The solar cell structure according to claim 35, wherein the nanostructures comprise an oxide material, an organic material, a semiconductor, or a metallic material.

42. The solar cell structure according to claim 35, further comprising:
a first electrode disposed on a portion of the second base; and
a second electrode disposed on a portion of the first base or the substrate.
